(19) United States
(12) Patent Application Publication
(10) Pub. No.: US 2002/0085342 A1
(43) Pub. Date: Jul. 4, 2002

(54) Portable computer with shockproof function

(76) Inventors: Shin-Chen Chen, Taipei (TW); Ming-Hsun Chou, Taipei (TW)

Correspondence Address: BACON & THOMAS, 625 Slaters Lane - 4th Floor, Alexandria, VA, 22314, US

(21) Appl. No.: 09/749,887

(22) Filed: Dec. 29, 2000

(51) Int. Cl. G06F 1/16; H05K 5/00

(52) U.S. Cl. 361/683; 312/223.1; 248/560; 248/609; 248/638

(57) ABSTRACT

Portable computer with shockproof function, including buffer structure with very good shockproof effect. The buffer structure is disposed on portions of outer surface of the portable computer which are subject to collision for absorbing impacting and shocking force and protecting the portable computer from being damaged. Snap structure is further disposed on the surface of the portable computer for detachably assembling with a back belt, enabling a user to hang the portable computer on the shoulder or carry the portable computer.

### BACKGROUND OF THE INVENTION

The present invention is related to a portable computer, and more particularly to a portable computer having buffer structure with very good shockproof effect. The buffer structure is disposed on portions of outer surface of the portable computer which are subject to collision for absorbing impacting and shocking force and protecting the portable computer from being damaged.

It is a trend to use portable computer in various fields. The portable computer has small volume and can be easily carried. In order to protect the portable computer from damaged due to collision when carried outdoors, the portable computer is designed with internal anti-collision and shockproof structure. However, the portable computer lacks shockproof structure on outer surface. Therefore, in case of unexpected collision or impact, the portable computer may be still damaged.

Moreover, the conventional portable computer is not equipped with any back belt or other carrying structure. Therefore, a user often needs to directly hold the portable computer with a hand or pack the portable computer in a case when carried outdoors. This leads to great inconvenience in carriage. In addition, the portable computer is liable to slip out of the hand and damage. A specific carrying bag for the portable computer helps in protecting the portable computer from damaging due to incautious dropping. However. it is troublesome to pack the portable computer into the carrying bag. Moreover, such specific carrying bag lacks shockproof design. As a result, in case of strong impact, the portable computer still can be hardly fully protected.

### SUMMARY OF THE INVENTION

It is therefore a primary object of the present invention to provide a portable computer with shockproof function. The portable computer includes buffer structure with very good shockproof effect. The buffer structure is disposed on those portions (such as corners or convex portions ) of outer surface of the portable computer which are subject to collision The buffer structure serves to absorb impacting and shocking force to protect the portable computer from being damaged.

It is a further object of the present invention to provide the above portable computer with shockproof function, in which the buffer structure is easily replaceable so that an old or a damaged buffer structure can be easily replaced with a new one.

It is a further object of the present invention to provide the above portable computer with shockproof function, in which snap structure is further disposed on the surface of the portable computer for detachably assembling with a back belt, whereby a user can hang the portable computer on the shoulder without packing the portable computer in a carrying bag or directly holding the portable computer with a hand. Therefore, the possibility of dropping of the portable computer can be minimized.

The present invention can be best understood through the following description and accompanying drawings wherein:

### BRIEF DESCRIPTION OF THE DRAWINGS

FIG. 1 is a perspective assembled view of a first embodiment of the present invention;

FIG. 2 is an enlarged exploded view of the buffer structure and the corner of the portable computer of FIG. 1; and

FIG. 3 is a perspective view of another embodiment of the present invention.

### DETAILED DESCRIPTION OF THE PREFERRED EMBODIMENTS

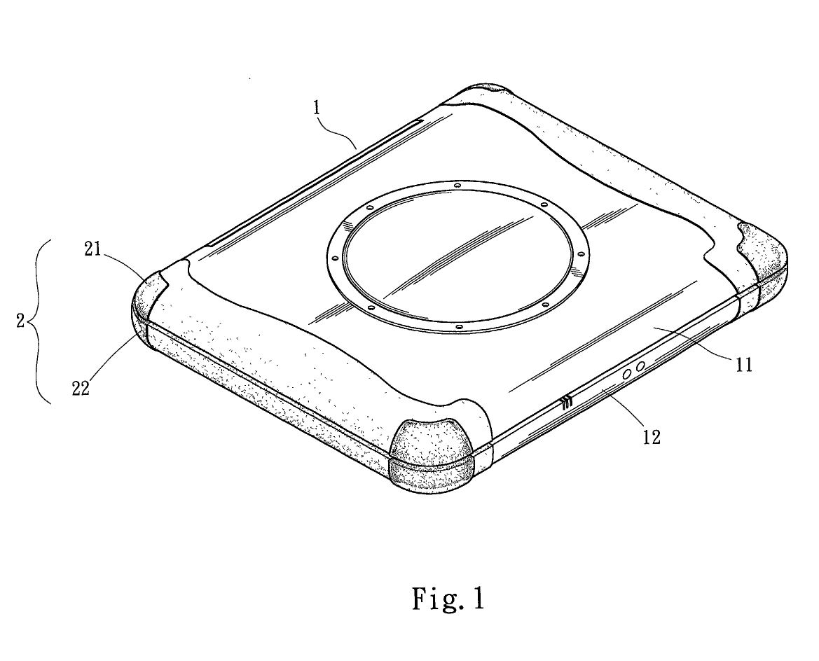

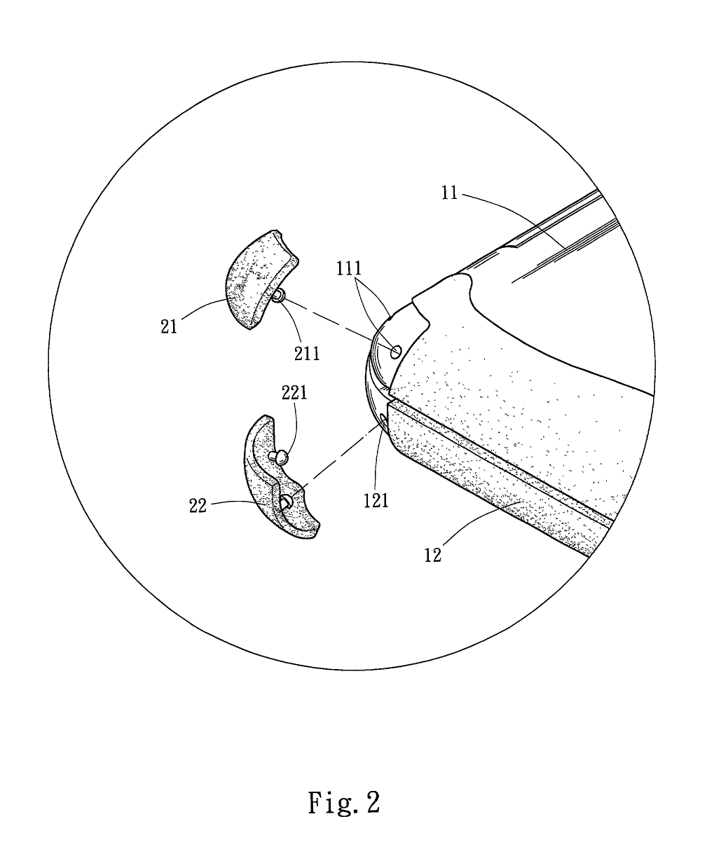

Please refer to FIGS. 1 and 2. The present invention includes a portable computer main body 1 and buffer structure 2. The walls of the corners of the upper cover 11 and base seat 12 of the main body 1 are formed with multiple insertion holes 111, 121. The buffer structure 2 is composed of buffer pads 21, 22 with very good shock-absorbent effect. The buffer pads 21, 22 are arched corresponding to the corners of the upper cover 11 and the base seat 12. The inner faces of the buffer pads 21, 22 are formed with substantially arrow-shaped insertion buttons 211, 221 projecting from the buffer pads 21, 22 corresponding to the insertion holes 111, 121. The insertion buttons 211, 221 are inserted into the insertion holes 111, 121 to firmly assemble the buffer pads with the main body. The buffer structure 2 serves to provide an anti-collision and shockproof ability for the portable computer I so as to protect the portable computer from being damaged.

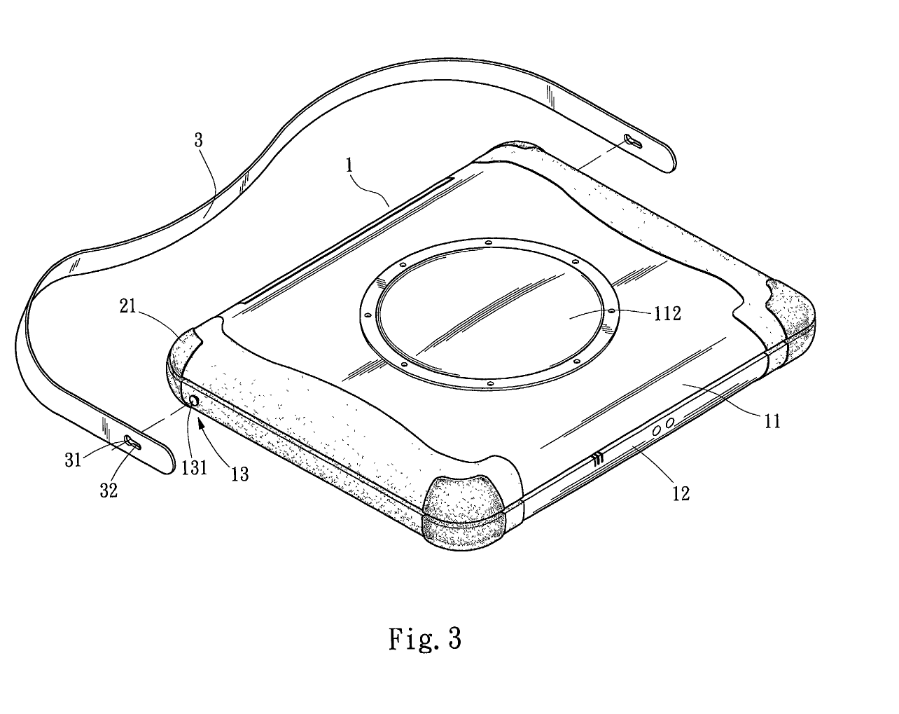

Referring to FIG. 3, a buffer pad 112 can be additionally disposed on the upper convex surface of the upper cover 11 of the portable computer main body. The buffer pad 112 is assembled with the main body by screws or other measures.

The buffer structure 2 is made of those materials with very good shock-absorbent effect (such as soft foam material). Alternatively, the buffer structure 2 can be made of inflatable air cushion. The insertion buttons can be easily detached from the insertion holes 111, 121 so that the old or damaged buffer pads 21, 22 can be freely replaced as necessary.

The pad bodies 2 can be alternatively directly adhered to the portable computer main body 1 to provide a protective effect for the portable computer.

FIG. 3 shows another embodiment of the present invention, in which two sides of the portable computer are further equipped with snap structure for detachably assembling with a carrying belt. Multiple arrow-shaped projecting buttons 13 are disposed on left and right sides of the main body 1. A free end of the projecting button 13 is formed with a bulge insertion end 131 which is latched in the latch hole 31 of the end of a back belt 3. The latch hole 31 is formed with a diameter for the insertion end 131 of the projecting button 13 to fit therein. The latch hole 31 has a locating slot 32 extending to the end of the back belt 3. The locating slot 32 has a dimension smaller than the latch hole 31. After the projecting button 13 is fitted into the latch hole 31, the back belt 3 is pulled to fit the projecting button 13 into the locating slot 32. Accordingly, the projecting button 13 is located in the locating slot 32 to assemble the back belt 3 with the portable computer 1 for hanging the portable computer 1 on the shoulder or carrying the portable computer. The snap structure can be replaced by a press button or other latching members to achieve the same function.

The above embodiments are only used to illustrate the present invention, not intended to limit the scope thereof. Many modifications of the above embodiments can be made without departing from the spirit of the present invention.

What is claimed is:

1. Portable computer with shockproof function, comprising a portable computer main body and buffer structure with very good shockproof effect, the buffer structure being disposed on portions of outer surface of the main body which are subject to collision.

2. Portable computer with shockproof function as claimed in claim 1, wherein the buffer structure is an inflatable air cushion.

3. Portable computer with shockproof function as claimed in claim 1, wherein the buffer structure is made of soft foam material.

4. Portable computer with shockproof function as claimed in claim 1, wherein the main body are formed with multiple insertion holes and the buffer structure is formed with insertion buttons corresponding to the insertion holes for inserting therein.

5. Portable computer with shockproof function as claimed in claim 1, wherein the buffer structure is adhered to the portable computer.

6. Portable computer with shockproof function as claimed in claim 1, wherein projecting buttons are disposed on two sides of the main body, the projecting buttons being latched in latch holes of a back belt for hanging the portable computer on the shoulder or carrying the portable computer.

7. Portable computer with shockproof function as claimed in claim 6, wherein a free end of the projecting button is formed with a bulge insertion end, the latch hole being formed with a diameter for the insertion end of the projecting button to fit therein, the latch hole having a locating slot extending to the end of the back belt, whereby after the projecting button is fitted into the latch hole, the back belt is pulled to fit and locate the projecting button in the locating slot for assembling the back belt with the portable computer.
